(19) United States
(12) Patent Application Publication
(10) Pub. No.: US 2026/0027923 A1
(43) Pub. Date: Jan. 29, 2026

(54) PLUG-IN CONNECTOR PART

(71) Applicant: Kiekert Aktiengesellschaft, Heiligenhaus (DE)

(72) Inventors: Christian STURM, Krefeld (DE); Michael BERRES, Köln (DE)

(73) Assignee: Kiekert Aktiengesellschaft, Heiligenhaus (DE)

(21) Appl. No.: 19/100,980

(22) PCT Filed: Jul. 28, 2023
(86) PCT No.: PCT/DE2023/100558

§ 371 Date: Feb. 4, 2025

(30) Foreign Application Priority Data
Aug. 10, 2022 (DE) 10 2022 120 131.7

(51) Int. Cl. B60L 53/16; H01R 13/10; H01R 13/502; H05K 7/20

(52) U.S. Cl. CPC B60L 53/16; H01R 13/10; H01R 13/502; H05K 7/20409; H05K 7/20463; H01R 2201/26

(57) ABSTRACT

The invention relates to a plug-in connector part for mechanical and electrical connection to a mating plug-in connector part, in particular relates to a charging socket (1) on a motor vehicle for coupling with a charging plug as constituent parts of an electric charging infrastructure for electric or hybrid motor vehicles, or vice versa, having a housing (2) composed of plastic and also having at least one electrical contact element (3), which is arranged in the housing (2). A cooling element (5), which is in thermal contact with the electrical contact element (3), is also realized. According to the invention, the contact element (3) and the cooling element (5) are electrically insulated from each other.

The invention relates to a plug-in connector part for mechanically and electrically connecting to a mating plug-in connector part, in particular a charging socket on the motor vehicle for coupling to a charging plug as components of an electric charging infrastructure for electric or hybrid motor vehicles, or vice versa, comprising a housing made of plastics and at least one electrical contact element arranged in the housing, and comprising a cooling element which is in thermal contact with the electrical contact element.

The plug connector part is generally a charging socket in a motor vehicle that can be coupled with an associated charging plug-for example, on an electrical charging station. The charging plug, alike the charging socket, is part of electric charging infrastructure used to charge the rechargeable energy storage units or accumulators of electric or hybrid motor vehicles. In principle, the plug connector part on the motor vehicle can also be a charging plug instead of a charging socket. In this case, the charging station is equipped with an associated charging socket. As a rule, however, the electric or hybrid motor vehicle has a charging socket with several electrical contact elements, located in the housing, into which the charging plug connected to the charging station is inserted to charge the motor vehicle in question.

In order to be able to supply the high electrical performance of the electric motors in the motor vehicle in question with the necessary electrical energy on the one hand and to provide a sufficient range on the other, high-voltage batteries or accumulators are used nowadays, which are typically charged with high-voltage direct current. In addition to such DC (direct current) charging processes, most electric or hybrid motor vehicles also allow the charging process to be carried out via an alternating voltage in the sense of an AC (alternate current) charging process. At this point, however, low currents and long charging times are usually used, whereas, in the DC charging process described above, high voltages and high currents and the resulting short charging times are observed.

In particular with DC charging processes, the fundamental problem arises that the electrical contact elements used at this point get hotter and hotter due to the high current. This increases resistance, which hinders the electrical charging process and fast charging, as is desired. In addition, due to the heat generated at or in a charging station, open-loop or closed-loop control of the charging current is necessary in order to take into account the possible increase in temperature of the contact element.

For this reason, the prior art according to EP 3 616 270 B1 describes a plug connector part including a temperature-monitoring device. If there is any overheating of the contact element, the temperature-monitoring device ensures that the power is switched off or at least reduced.

In the generic prior art according to EP 3 433 904 B1, the contact element in said document is equipped with a heat capacity element in the form of a cooling element. This is intended to optimize and accelerate heat dissipation from the contact element to the environment. In the best case, this allows high currents to be transmitted without activating a potential and additionally provided temperature-monitoring device. This has proven to be fundamentally successful.

However, the prior art according to EP 3 433 904 B1 on the whole proceeds in such a way that the individual heat capacity elements or cooling elements to be connected to a shaft portion of the contact element in a force-locking or form-locking manner via an attachment piece. The cooling elements are solid cuboidal metal bodies. As a result, the available installation space inside the plug-in connector part or the charging socket is reduced on the one hand. On the other hand, increased weight alongside increased costs and the risk of electrical short circuits still occurring are observed. For this purpose, in the prior art, the cooling elements of different contact elements are electrically insulated from one another.

However, this still results in the problem that the cooling elements may be subject to high voltage due to being electrically coupled to the contact elements, wherein the insulation between the individual cooling elements may electrically insulate them from one another, but may not provide sufficient electrical insulation from other components inside the plug-in connector part or from the outside either. This may be problematic, especially in the light of constantly increasing direct voltages or high voltages in this region. The invention as a whole seeks to remedy this.

The technical problem addressed by the invention is that of developing such a plug-in connector part in such a way that both perfect heat dissipation and cooling as well as reliable electrical insulation are observed even when a high voltage is applied.

To solve this technical problem, the invention proposes that in a plug-in connector part of the type in question for mechanically and electrically connecting to a mating plug-in connector part, the contact element and the cooling element are electrically insulated from one another.

In contrast to the generic prior art according to EP 3 433 904 B1, according to the invention the cooling element and the contact element firstly cannot form an electrical connection with one another, but are instead electrically insulated from one another. In contrast, the known generic teaching works in such a way that at this point the cooling elements are each connected to the shaft portion of the contact element in a force-fitting or form-fitting manner by means of an attachment piece. This means that at this point an electrical connection is deliberately propagated-contrary to the teaching of the invention.

Electrically insulating the contact element from the cooling element while simultaneously forming a thermally conductive connection, can be implemented in different ways in detail. According to a first variant, it is therefore possible in principle for the cooling element to be electrically insulating and at the same time thermally conductive. One variant in which the cooling element consists of or has been manufactured from, for example, a thermally conductive plastics or polymer has proven to be particularly advantageous. At the same time, this allows the cooling element to be designed as an electrically insulating cooling element.

The thermally conductive polymer can be one in which individual fillers are embedded for conducting heat. The invention is based on the knowledge that thermoplastics typically used for producing the plastics housing for the plug-in connector part generally have degrees of thermal conductivity of at most 0.5 W/m·K. This means that the plastics materials typically used in this context, such as polypropylene (PP), PA (polyamide), polyethylene terephthalate (PET), polyethylene (PE), etc., have the aforementioned typical values in respect of their degree of thermal conductivity.

Nevertheless, in order to provide a cooling element with increased thermal conductivity, which is also electrically insulating, a suitable filler can be embedded in the plastics material in question. Electrically insulating and simultaneously thermally conductive fillers have proven to be particularly advantageous here. They include, for example, aluminum compounds or boron compounds, particularly preferably aluminum oxide or boron nitride to be specific. This makes it possible to increase the thermal conductivity of the plastics material in question by at least a factor of 3, so that a corresponding cooling element in this context has degrees of thermal conductivity of at least 1.5 W/m·K.

In this context, the thermally conductive fillers in question in the plastics for producing the cooling element can be provided in a grammage of up to 50 wt. % or more. At this point, further details regarding the fillers and the associated plastics can be found in the relevant document DE 10 2007 037 316 A1, which represents the relevant prior art. Said publication deals with thermally conductive and electrically insulating thermoplastic compounds, i.e., plastics with the embedded specific fillers mentioned above. Reference is also made to DE 10 2013 208 605 A1.

In addition to the already described possibility of designing the cooling element to be electrically insulating and at the same time thermally conductive, the invention opens up the possibility of the contact element and the cooling element being thermally conductively coupled to one another via an electrically insulating heat transfer element as a further option. In this way, the cooling element itself can be designed to be simultaneously electrically and thermally conductive; for example, it can be realized as a metal cooling element. In particular, metals such as steel, aluminium or zinc have proven to be particularly suitable here. In this case, the necessary electrical insulation is not provided by the cooling element itself, but rather by the electrically insulating heat transfer element, which is arranged between the electrically conductive contact element and the cooling element, which in this case is also electrically conductive.

It is, of course, in principle also possible to use the electrically insulating heat transfer element in question, if required, for an electrically non-conductive and at the same time thermally conductive cooling element made of the described plastics material comprising embedded fillers. This ultimately depends on how high the electrical conductivity of the cooling element still is or is set. This means that, depending on the fillers embedded in the plastics material in question for realizing the cooling element, the electrically insulating heat transfer element may or may not additionally be arranged between the contact element and the cooling element, if required.

In connection with the electrically insulating heat transfer element, it has proven to be particularly advantageous for this to be designed as a component of the plastics housing. This means that additional manufacturing measures and special production methods are not required. In this context, it is particularly advantageous if the heat transfer element encloses the contact element in the shape of a ring in cross section or on the whole cylindrically with a wall thickness of in particular a few millimeters. Here, it is advantageously even possible to use wall thicknesses of less than 1 mm.

The heat transfer element, which is designed as a component of the housing, can again be defined by fillers introduced into the plastics. These fillers are only introduced into the plastics in the region of the heat transfer element. Here, electrically insulating fillers with increased thermal conductivity can, in turn, be used, as already described at the outset. Particularly suitable for this purpose are aluminum and boron compounds and in particular aluminum oxide or boron nitride, which are introduced into the plastics of the housing provided in the region of the heat transfer element and in this way define the electrically insulating and at the same time thermally conductive heat transfer element.

Alternatively or additionally, the heat transfer element can, however, also be designed as a component that is independent of the housing. In this case, it is alternatively conceivable that the heat transfer element is a bulk material made of, for example, a ceramic or mineral material. Alternatively or additionally, the heat transfer element, which is independent of the housing, can, however, also be designed as a hose clamp which at least largely encloses the electrical contact element. It is also possible that the heat transfer element comprises such a hose clamp.

In the latter case, the heat transfer element is typically formed of two parts and is usually composed of an actual transfer element that surrounds the contact element in question in the shape of a ring and also a clamping sleeve. By means of the clamping sleeve, the heat transfer element including the electrical contact element can be placed in a hole in the housing. This compresses the clamping sleeve or hose clamp. The clamping sleeve or hose clamp has a high degree of thermal conductivity because the heat transfer element located thereinside primarily provides electrical insulation and at the same time heat conduction at this point.

This results in a plug-in connector part that is characterized by particularly favorable thermal management. This can be attributed to the fact that a cooling element is used which is electrically insulated from the contact element. This prevents any high voltage present at the contact element from being transferred to the cooling element. In order to realize this in detail, it is possible to either use a cooling element that is based on plastics or a polymer with embedded fillers or in such a way that an electrically insulating heat transfer element is additionally arranged between the contact element and the cooling element. Of course, the two fundamental measures described above can also be combined with one another.

In any case, it is ensured that either the cooling element itself is electrically insulating and at the same time thermally conductive or, if the cooling element is electrically conductive, the interposed heat transfer element ensures electrical insulation toward the contact element. These are the main advantages.

In the following, the invention is explained in more detail with the aid of a drawing showing only an exemplary embodiment; in the figures:

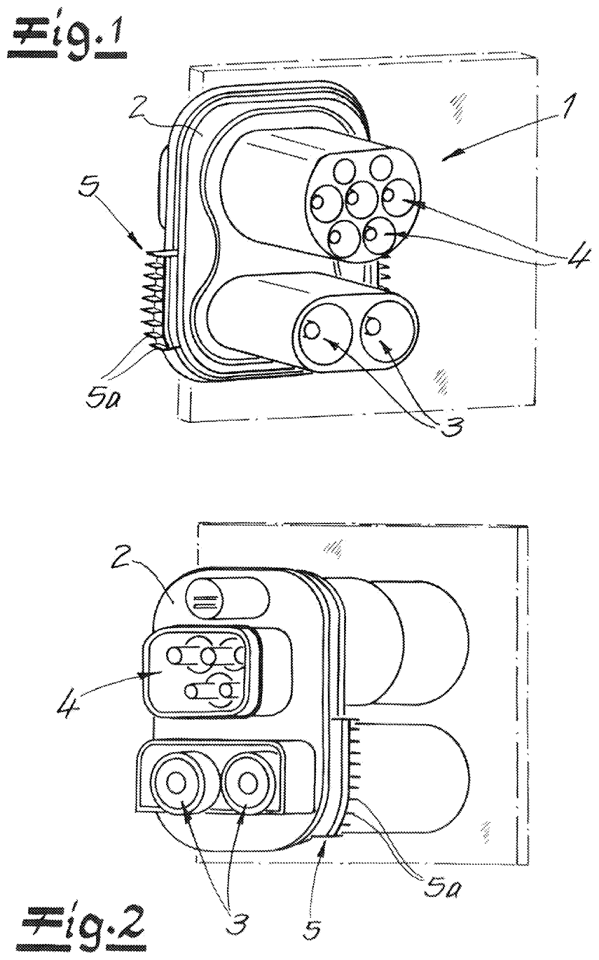

FIG. 1 shows a front view of the plug connector part according to the invention in the form of a motor vehicle-side charging socket,

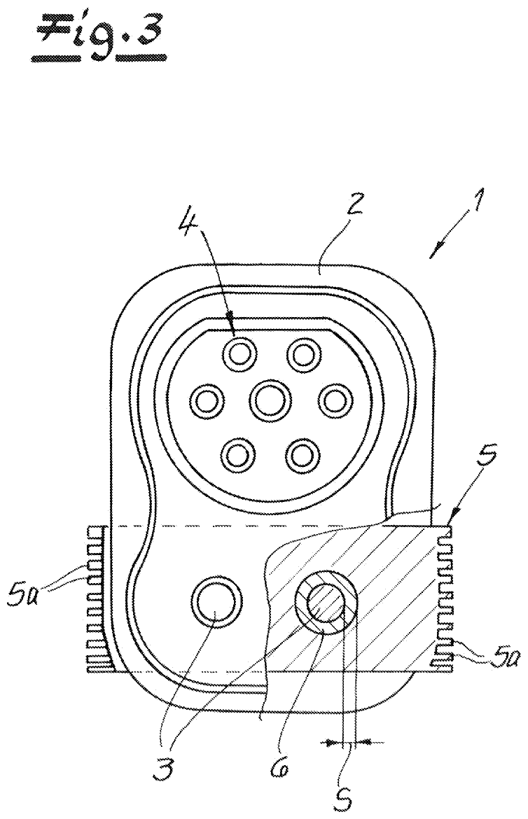

FIG. 2 shows the associated rear view to FIG. 1,

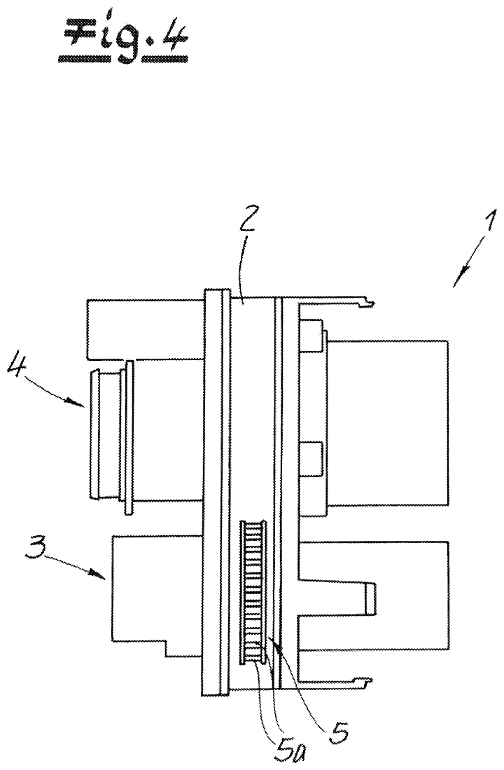

FIG. 3 shows a front view of the subject matter according to FIGS. 1 and 2, and

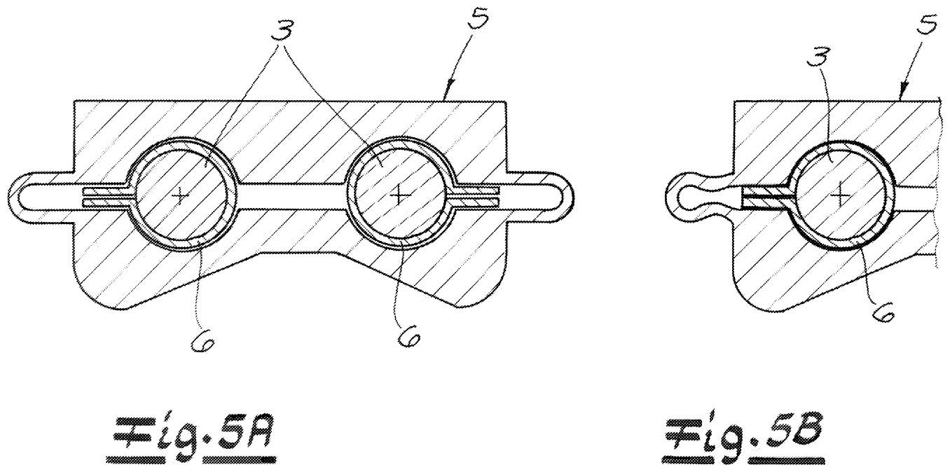

FIG. 4 shows a side view of the subject according to FIG. 3.

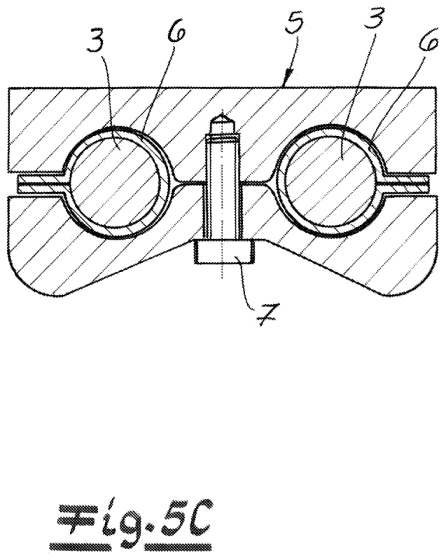

FIGS. 5A, B, C show a modified embodiment, and

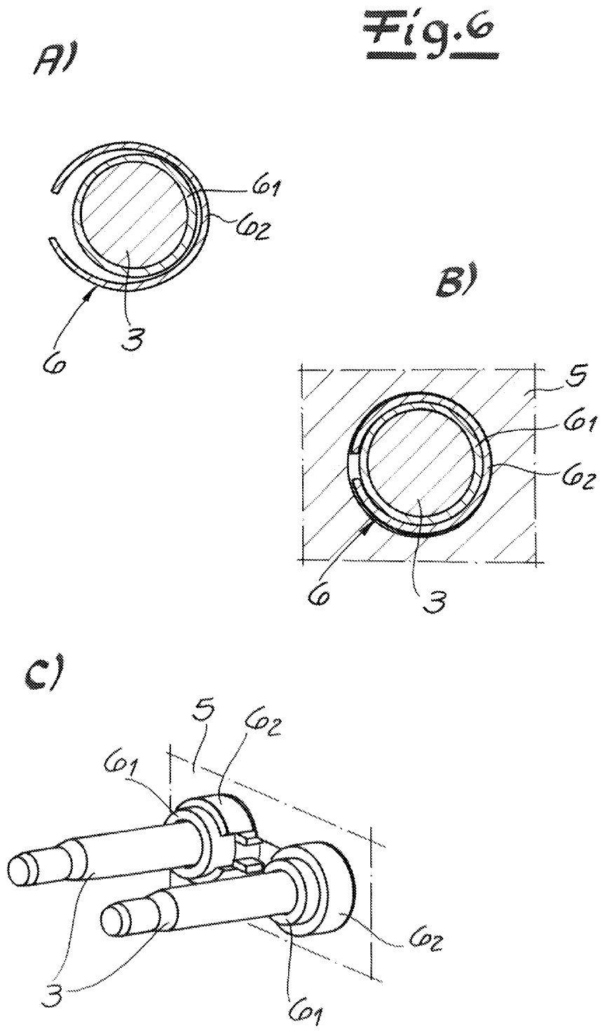

FIGS. 6A, B, C show a further variant of the invention.

The figures show a plug connector part for mechanical and electrical connection with a mating plug connector part. In fact, the plug-in connector part according to the embodiment in FIGS. 1 and 2 is a charging socket 1 on the motor vehicle. The charging socket 1 is designed to be coupled to a charging plug, which is not shown in detail and is a component of an electrical charging infrastructure for electric or hybrid motor vehicles.

For this purpose, the charging socket 1 is equipped with a housing 2 made of plastic and at least one electrical contact element 3 located in the housing 2. In the following, only the two contact elements 3 required for a DC charging process are considered in more detail. The additionally provided further electrical contact elements 4 which, in contrast, are required for an AC charging process, will not be discussed in more detail. According to the embodiment, the two electrical contact elements 3 inside the housing 2 are equipped with a cooling element 5. The cooling element 5 is in thermal contact with the electrical contact element 3.

On the whole, this is interpreted as shown in detail in the front view according to FIG. 3 and the side view in FIG. 4. Within the scope of the invention, there are a total of two different variants to be implemented. In fact, according to a first variant, it is possible for the cooling element 5 to be designed to be electrically insulating and at the same time thermally conductive. In this case, the cooling element 5 may be one made of a plastics or polymer and thus a component of the housing in which fillers are embedded that are designed to be electrically insulating and at the same time thermally conductive. Suitable fillers have already been described at the outset and can be, for example, aluminum oxide and/or boron nitride. In this case, an additional electrically insulating heat transfer element 6 between the contact element 3 and the cooling element 5, as indicated in FIG. 3, is unnecessary.

On the whole, however, the electrically insulating heat transfer element 6 is used in the embodiment according to FIGS. 3 and 4. By means of the electrically insulating heat transfer element 6, the contact element 3 and the cooling element 5 are coupled to one another in a thermally conductive manner. In this case, the cooling element 5 is advantageously made of a metal such as steel, aluminum or zinc. Of course, combinations are also conceivable. In this context, so that the cooling element 5 made of metal is not exposed to the high voltage applied to the contact element 3, the electrically insulating heat transfer element 6 ensures electrical decoupling between the contact element 3 and the cooling element 5 in this case. In contrast, the variant already described above is characterized by the fact that the heat transfer element 6 is not necessary because the cooling element 5 itself provides the electrical insulation.

In the variant according to FIGS. 3 and 4, the heat transfer element 6 can consist of and be made from a foreign material (i.e., not from plastic). Ceramic or mineral materials have proven to be particularly suitable here, as they provide electrical insulation while still being thermally conductive at the same time. Suitable ceramic materials include zirconium, for example, and mineral materials such as sand or the like can be used.

In addition, this is interpreted on the whole as the heat transfer element 6 enclosing the contact element 3 in the shape of a ring in cross section with a wall thickness S of in particular a few millimeters. In fact, the wall thickness S of the heat transfer element 6 can be a few millimeters and even below 1 mm. In this way, particularly favorable and rapid heat transfer from the contact element 3 to the cooling element 5 is realized and implemented, which corresponds to particularly effective cooling.

On the basis of the embodiment, it can be seen that, on the whole, the cooling element 5 is strip-shaped and has cooling fins 5a at the end. These cooling fins 5a can protrude laterally beyond the housing 2 when viewed from the front. This depends on the installation and space conditions for the charging socket 1. It can also be seen that the cooling element 5 only encloses the contact elements 3 for the DC charging process in the shape of a strip, whereas the other contact elements 4 for the AC charging process are not covered due to the lower currents there.

The above-described variant according to each of FIGS. 3 and 4 is designed in such a way that the heat transfer element 6 is made of a foreign material (i.e., not of plastics). In this case, the heat transfer element 6 is designed as a component that is independent of the housing 2 or the cooling element 5. FIGS. 5 and 6 also show a variant in which the heat transfer element 6 is designed as a component that is independent of the housing 2 or the cooling element 5.

In fact, it can be seen from FIG. 5A that in this case the heat transfer element 6 in this figure is designed as a hose clamp that at least largely encloses the electrical contact element 3. This can be done in such a way that after pre-assembly of the electrical contact element 3 and the housing 2 or its cooling element 5, the heat transfer elements 6 shown, which are each designed as double-ear hose clamps, are deformed in air gaps in the housing 2 or the cooling element 5 and largely eliminate or close them. A similar situation applies to the further variant also shown in FIG. 5B, according to which a screw 7 or another clamping means ensures at this point that any air gaps remaining after pre-assembly are eliminated, and therefore continuous heat flow from the contact element 3 to the housing 2 or its cooling element 5 via the heat transfer element 6 is observed and present.

The further variant according to FIG. 6 is characterized by a two-part heat transfer element 6₁, 6₂, so to speak, which in turn is designed as a component that is independent of the housing 2 or its cooling element 5. Firstly, a primary heat transfer element 61 which completely encloses the electrical contact element 3 is realized, which ensures that the contact element 3 is electrically decoupled from the housing 2 or cooling element 5. This primary heat transfer element 61 can be a coating of the electrical contact element 3 made of plastics or a polymer with embedded fillers that are designed to be electrically insulating and at the same time thermally conductive.

In addition to this primary heat transfer element 61, a secondary heat transfer element 62 is then provided, which is designed as a clamping sleeve. The clamping sleeve in question can be provided with a significantly improved degree of thermal conductivity compared to the primary heat transfer element 61. This results in assembly advantages, as can be seen from the perspective view additionally shown in FIG. 6.

In fact, in this context, the clamping sleeve in question or the secondary heat transfer element 62 and the electrical contact element 3 including the primary heat transfer element 61 can be moved so to speak into a pre-assembled position in an associated hole or recess in the cooling element 5 (shown in part) without requiring assembly force. During this process, the clamping sleeve or the secondary heat transfer element 61 is compressed and pressed with a slight transition fit into the hole in the cooling element 5. On the whole, this can be done without any tools and therefore results in a cost-effective and lightweight, yet nevertheless functionally reliable, variant.

### LIST OF REFERENCE SIGNS

1 Charging socket
2 Housing
3 Contact elements
4 Additional contact elements
5 Cooling element
5a Cooling fins
6 Heat transfer element
61, 62 Heat transfer element
S Wall thickness

1. A plug-in connector part for mechanically and electrically connecting to a mating plug-in connector part, or vice versa, the plug-in connector part comprising:
a housing made of plastics and
at least one electrical contact element arranged in the housing, and comprising
a cooling element in thermal contact with the at least one electrical contact element,
wherein the contact element and the cooling element are electrically insulated from one another.

2. The plug-in connector part according to claim 1, wherein the cooling element is electrically insulating and at the same time thermally conductive.

3. The plug-in connector part according to claim 2, wherein the cooling element includes a thermally conductive polymer.

4. The plug-in connector part according to claim 1, wherein the at least one contact element and the cooling element are thermally conductively coupled to one another via an electrically insulating heat transfer element.

5. The plug-in connector part according to claim 4, wherein the electrically insulating heat transfer element encloses the at least one contact element in a shape of a ring in cross section having a wall thickness.

6. The plug-in connector part according to claim 5, wherein the wall thickness is below 1 mm.

7. The plug-in connector part according to claim 4, wherein the electrically insulating heat transfer element is designed as a component of the housing.

8. The plug-in connector part according to claim 7, wherein the heat transfer element comprises fillers that are embedded in the plastics of the housing.

9. The plug-in connector part according to claim 4, wherein the electrically insulating heat transfer element is designed as a component that is independent of the housing.

10. The plug-in connector part according to claim 9, wherein the heat transfer element is designed as a bulk material including a ceramic or mineral material and/or a hose clamp at least largely enclosing the contact element.

11. The plug-in connector part according to claim 5, wherein the wall thickness is at least 1 mm.

12. The plug-in connector part according to claim 4, wherein the electrically insulating heat transfer element is a hose clamp.

13. The plug-in connector part according to claim 8, wherein the fillers include aluminum oxide or boron nitride.

14. The plug-in connector part according to claim 4, wherein the electrically insulating heat transfer element includes a primary heat transfer element and a secondary heat transfer element.

15. The plug-in connector part according to claim 14, wherein the secondary heat transfer element is a clamping sleeve.

16. The plug-in connector part according to claim 14, wherein the secondary heat transfer element has an greater thermal conductivity relative to the primary heat transfer element.
